(19) United States
(12) Patent Application Publication
(10) Pub. No.: US 2005/0208749 A1
(43) Pub. Date: Sep. 22, 2005

(54) Methods for forming electrical connections and resulting devices

(76) Inventors: Michael W. Beckman, Portland, OR (US); Gary B. Long, Aloha, OR (US); Gary A. Brist, Yamhill, OR (US); William O. Alger, Portland, OR (US); Jayne L. Mershon, Corbett, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/803,427

(22) Filed: Mar. 17, 2004

(51) Int. Cl. H01L 21/44; H01L 21/50

(52) U.S. Cl. 438/613; 438/612; 438/614; 438/108

(57) ABSTRACT

Methods for forming electrical connections between two components, as well as various embodiments of devices created according to the disclosed methods, are described. The method includes forming a depression in a land disposed on a first component, wherein the depression is shaped to receive a conductive bump extending from a second component. A layer of conductive material is disposed between the land and the conductive bump, and the conductive material layer is used to form an electrical connection between the land and conductive bump.

### FIELD OF THE INVENTION

The disclosed embodiments relate generally to integrated circuit devices and, in particular, to methods for forming electrical connections between two components.

### BACKGROUND OF THE INVENTION

To package an integrated circuit (IC) die, such as a processing device or memory device, the IC die is typically mounted on a substrate, this substrate often referred to as the “package substrate.” The IC die includes a number of leads, or “bond pads,” that are coupled with a corresponding number of leads, or “lands,” disposed on one surface of the package substrate. One technique for coupling the bond pads of the die to the lands of the package substrate is to use a ball grid array (BGA), wherein each of the die bond pads is coupled with a package substrate land by a solder bump (e.g., a generally spherical ball, a column, or other connection element). The solder bumps may be formed on the die, and a solder reflow process performed to attach each of the solder bumps to its corresponding land on the package substrate. The above-described process is, for example, employed in a Controlled Collapse Chip Connect (or “C4”) assembly scheme.

The package substrate includes circuitry to route signals to and from the IC die. This circuitry routes at least some of the IC die leads to locations on the package substrate where electrical connections can be established with a next-level component, such as a circuit board, a motherboard, a computer system, another IC device, etc. For example, the package substrate circuitry may route some of the die leads to an array of leads formed on an opposing surface of the package substrate. The leads on the opposing surface of the package substrate may then be coupled to a corresponding set of leads provided on the next-level component using a BGA assembly technique, as described above. Each lead on the opposing surface of the package substrate has a solder bump (or other connection element) formed thereon, and a solder reflow process is performed to connect the array of solder bumps on the package substrate to the corresponding array of leads on the next-level component.

An example of a conventional packaged IC device 100 is illustrated in FIG. 1. The IC device 100 may, for example, comprise a processing device (e.g., a microprocessor, network processor, etc.), a memory device, or any other integrated circuit device. Referring to FIG. 1, the IC device 100 includes a die 130 that is disposed on a package substrate 120 which, in turn, is coupled with a circuit board 110 (or other next-level component). Die 130 includes a number of bond pads 137 and package substrate 120 includes a corresponding number of lands 125 disposed on one surface 121 thereof, and a plurality of solder bumps 150 (e.g., generally spherical balls) connect the die bond pads to the substrate lands 125. Similarly, package substrate 120 includes a number of leads 127 on an opposing surface 122, and another set of solder bumps 140 couples these leads of package substrate 120 to a corresponding number of leads 115 disposed on board 110. Circuitry within package substrate 120 routes signals between the board 110 and the leads of die 130, as previously described.

Turning to FIG. 2, an enlarged view of a portion of the IC device 100 is shown. In particular, FIG. 2 illustrates a connection between the die 130 and one of the lands 125 on package substrate 120. As shown in this figure, the land 125 has a generally flat surface 129 that interfaces with solder bump 150. Again, a solder reflow process may be used to connect solder ball 150 to land 125 on package substrate 120. Typically, the leads (or lands) 115 on board 110 would include a similar flat geometry.

Demand for greater I/O (input/output) density for IC devices is pushing manufacturers to reduce the size of the lands on package substrates and/or circuit boards (and other next-level components). For a BGA connection technique, as the size of these lands decreases, the surface area of contact between a land and its mating solder bump may also decrease. A smaller contact area between a BGA bump and its mating lead can result in increased resistance and, hence, lower electrical conductivity. Also, the conventional flat land geometry provides minimal registration between an array of solder bumps and a mating array of lands (although surface tension between the solder bumps and their mating lands may tend to “pull” two mating components into alignment during the reflow process). Furthermore, low temperature applications (e.g., polymer memory devices) may not be amenable to a BGA connection technique, as the temperatures required for the reflow process employed in conventional BGA processing may be unsuitable for these low temperature applications.

### BRIEF DESCRIPTION OF THE DRAWINGS

FIG. 1 is a schematic diagram illustrating an embodiment of a conventional packaged IC device.

FIG. 2 is an enlarged schematic diagram illustrating a portion of the packaged IC device shown in FIG. 1A.

FIG. 3A is a schematic diagram illustrating one embodiment of a connection between two components.

FIG. 3B is a schematic diagram illustrating an enlarged portion of the embodiment shown in FIG. 3A.

FIGS. 4A-4B are schematic diagrams, each illustrating an embodiment of the land shown in FIG. 3, each figure including perspective and cross-sectional views.

FIG. 5 is a schematic diagram illustrating another embodiment of a connection between two components.

FIG. 6 is a schematic diagram illustrating an embodiment of the land shown in FIG. 5, this figure including perspective and cross-sectional views.

FIG. 7 is a block diagram illustrating an embodiment of a method of forming electrical connections between the leads of two components.

FIGS. 8A-8D are schematic diagrams further illustrating the method shown in FIG. 7.

FIG. 9 is a schematic diagram illustrating an embodiment of a packaged IC device.

FIG. 10 is a schematic diagram illustrating an embodiment of a computer system, which may include a component formed according to the disclosed embodiments.

### DETAILED DESCRIPTION OF THE INVENTION

Disclosed below are various embodiments of a method of forming electrical connections between two components, as well as embodiments of devices formed according to the disclosed methods. In one embodiment, the disclosed methods for forming electrical connections may find application to BGA packages. In another embodiment, the disclosed embodiments may find use in low temperature applications (e.g., temperatures less than those temperatures employed in solder reflow processes). In a further embodiment, the disclosed embodiments may be used in the registration and alignment of two components. It should be understood, however, that the disclosed embodiments are not limited to BGA packaging techniques or to low temperature applications.

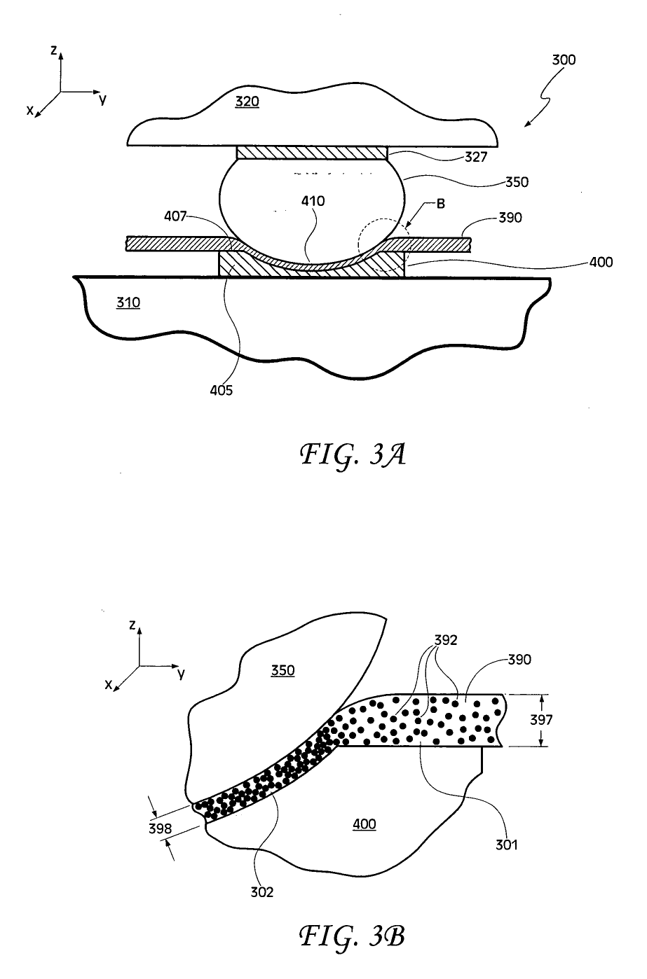

Turning to FIG. 3A, a portion of an assembly 300 is shown. The assembly 300 comprises a first component 310 and a second component 320. In one embodiment, the first component 310 comprises a package substrate and the second component 320 comprises an integrated circuit (IC) die. In another embodiment, the second component 320 comprises a package substrate, whereas the first component 310 comprises a circuit board or other next-level component. It should be understood, however, that the first and second components may comprise any other devices that are in (or that are ultimately to be in) electrical communication. The first component 310 includes a lead or land 400, and the second component 320 includes a lead or bond pad 327. A conductive bump 350 (e.g., a generally spherical ball, a column, or other connection element) is disposed on the bond pad 327, and this conductive bump will form an electrical connection with the land 400, as will be described below. Conductive bump 350 may be formed from any suitable conductive material, such as a solder material.

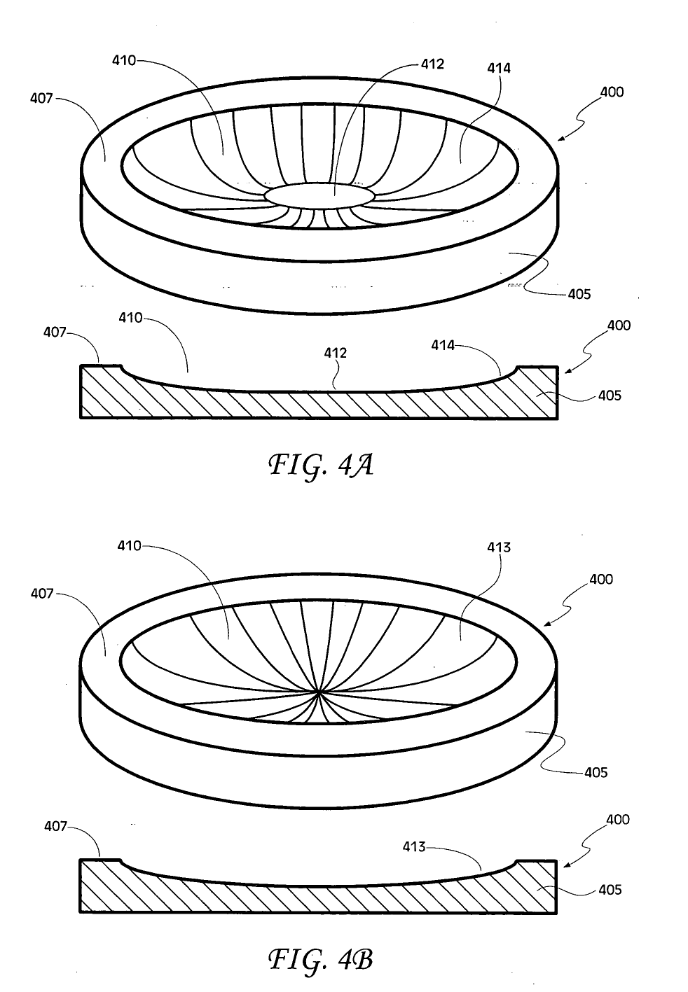

In one embodiment, the land 400 comprises a generally cylindrical disk shaped body 405 formed from a conductive material (e.g., copper or a copper alloy). Formed on an upper surface 407 and extending into the body 405 is a depression 410. The depression 410 is shaped to receive the conductive bump 350 extending from the second component 320, as shown in FIG. 3A. The depression 410 may be of any suitable shape, provided the depression can mate with and receive the conductive bump 350. By way of example, referring to FIG. 4A, the land 400 may include a depression 410 comprising a substantially flat bottom surface 412 and a rounded surface 414 extending upwards from the bottom surface 412 to the upper surface 407. By way of further example, as shown in FIG. 4B, the land 400 may include a depression 410 having a generally spherical contoured surface 413 extending down from upper surface 407. It should, however, be understood that FIGS. 4A and 4B are but a few examples of the shape and configuration of depression 410. Further, it should be noted that the shape and contour of the land 400 and the shape and contour of the conductive bump 350 do not necessary need to be congruent and/or precisely matched, so long as sufficient electrical contact can be established between bump 350 and land 400 (using a conductive material layer, as will be described below).

Returning to FIG. 3A, disposed over the land 400 and depression 410—and between the land 400 and the conductive bump 350—is a layer or film of a conductive material 390. The conductive material layer 390 forms an electrical connection between the conductive bump 350 and the mating land 400. In one embodiment, the conductive material layer 390 comprises an anisotropic conductive material. In a further embodiment, the anisotropic material comprises a carrier material (e.g., a polymer) in which a plurality of conductive particles are suspended. In this embodiment, the anisotropic material is compressed between the land 400 and conductive bump 350 in a region overlying the depression 410. The anisotropic material is compressed to an extent that the suspended conductive particles in the region overlying depression 410 are in sufficient contact with one another to form an electrical connection between the conductive bump 350 and land 400 (e.g., the anisotropic material is conductive in at least the Z-direction in this region).

The above-described compression of the anisotropic conductive film is further illustrated in FIG. 3B, which shows an enlarged view of region B in FIG. 3A. Referring to this figure, the anisotropic film 390 has an uncompressed thickness 397 in a region 301 that is generally outward of the depression 410 in land 400. In a region 302 between the land 400 and conductive bump 350, the anisotropic film 390 has been compressed to a second, narrower thickness 398.

Anisotropic material 390 comprises a plurality of conductive particles 392 that are suspended in a carrier, such as an epoxy material. In the uncompressed region 301, the conductive particles do not make sufficient electrical contact with one another to provide electrical conductivity in directions perpendicular and/or parallel to the first and second components 310, 320. Therefore, in regions outward of the land 400, the anisotropic film 390 is essentially non-conductive. However, in a compressed region 302, the anisotropic layer 390 has been compressed to a thickness such that the conductive particles 392 make sufficient electrical contact with one another to provide for electrical conductivity in at least a direction perpendicular to the land 400 (e.g., in the z-direction). Accordingly, the compressed region 302 of the anisotropic conductive film 390 provides electrical connectivity between the land 400 and conductive bump 350. In one embodiment, the anisotropic conductive film 390 is compressed up to approximately 50% of its original, uncompressed thickness.

In yet another embodiment, the conductive material layer 390 also comprises an adhesive material, and the conductive material layer 390 bonds the conductive bump 350 to the land 400, thereby providing a mechanical attachment (in addition to electrical connectivity) between the first and second components 310, 320. It should be understood that the disclosed embodiments are not limited to use of a conductive material layer 390 that is adhesive and/or that is an anisotropic.

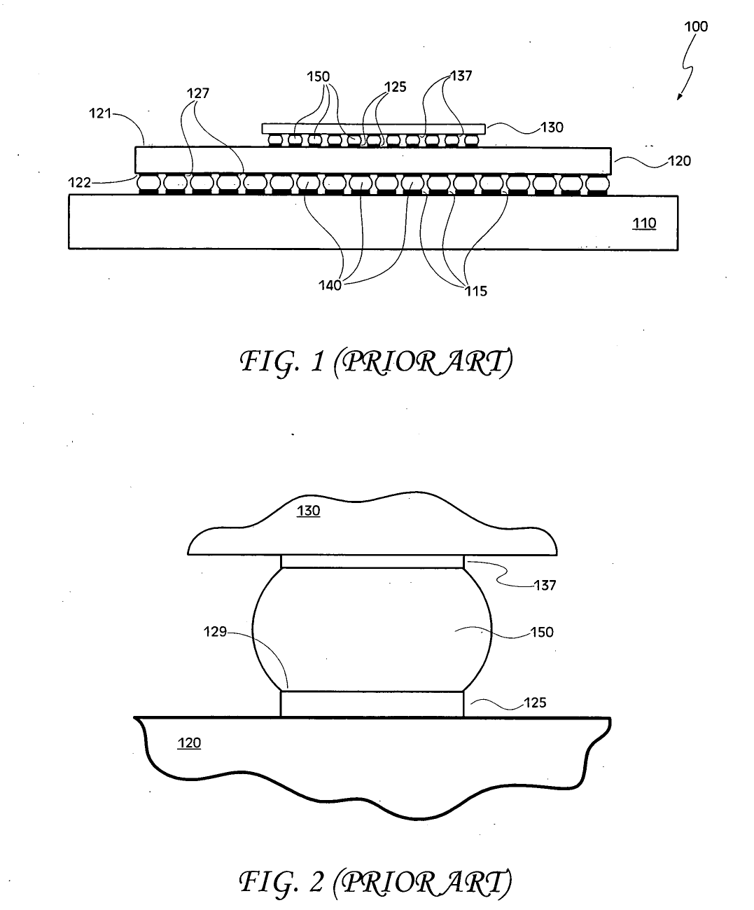

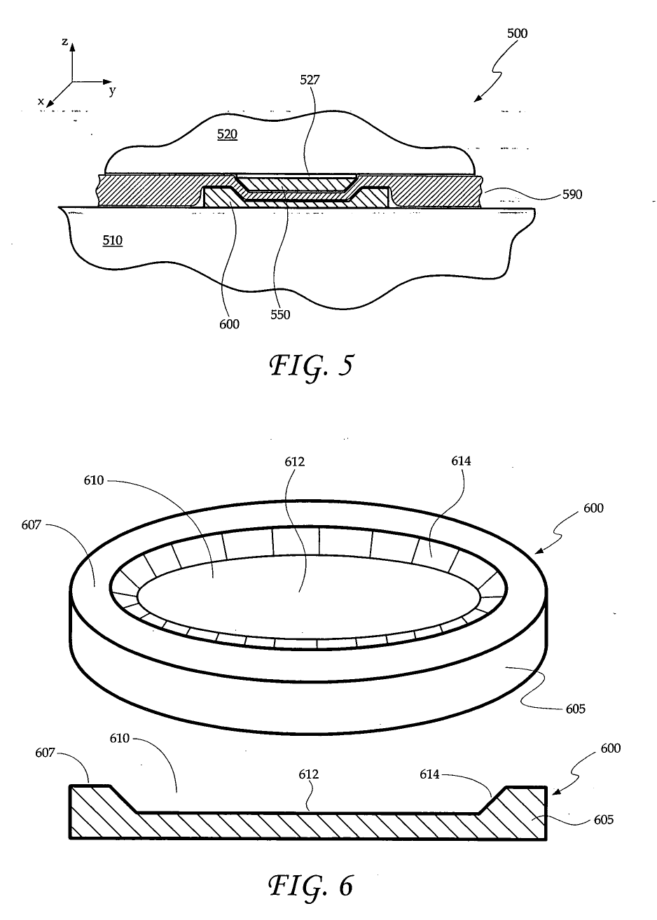

It should be noted that, in one embodiment, the three-dimensional geometry of the land 400 (e.g., depression 410) provides a greater surface area of contact between the conductive bump 350 and land 400 (as compared to the flat land geometry shown in FIGS. 1 and 2). This increase in contact surface area may provide lower resistivity and, hence, increased conductivity. The disclosed three-dimensional land geometry may be suited to applications requiring greater I/O density, as the land geometry of FIGS. 3A-4B (and FIGS. 5-6) may provide greater contact surface area where land sizes (and sizes of the conductive bumps) are being reduced. In another embodiment, the mating interaction between conductive bump 350 and the depression 410 of land 400 may assist in the registration and alignment between these two elements. Also, in a further embodiment, because the conductive film 390 is used to form an electrical connection between the conductive bmp 350 and land 400, a solder reflow process may not be needed to join these elements. Thus, the connection scheme illustrated in FIGS. 3A-4B (as well as in FIGS. 5 through 9) may be suitable for low temperature applications, such as polymer memory devices.

Referring now to FIG. 5, a portion of an assembly 500 is shown. The assembly 500 includes a first component 510 and a second component 520. In one embodiment, the first component 510 comprises a package substrate and the second component 520 comprises an IC die. In another embodiment, the second component comprises a package substrate, and the first component comprises a circuit board or other next-level component. However, it should be understood that the first and second components may comprise any other devices in electrical communication. First component 510 includes a lead or land 600, and the second component 520 includes a lead or bond pad 527. A conductive bump 550 is disposed on the bond pad 527, and this conductive bump will form an electrical connection with the land 600, as will be described below. In the embodiment of FIG. 5, the conductive bump 550 comprises a column shape having a tapered edge. Conductive bump 550 may be formed from any suitable conductive material, such as a solder material.

In one embodiment, the land 600 comprises a generally cylindrical disk shaped body 605 formed from a conductive material (e.g., copper or a copper alloy). Formed on an upper surface 607 and extending into the body 605 is a depression 610. Depression 610 is shaped to receive the conductive bump 550 extending from the second component 520. As shown in FIG. 6, the land 600 includes a depression 610 comprising a substantially flat bottom surface 612 and a tapered surface 614 extending upwards from the bottom surface 612 to the upper surface 607. As shown in FIG. 5, the tapered column shape of conductive bump 550 substantially corresponds to the shape of depression 610. Again, as suggested above, it is not required that the shape and contour of conductive bump 550 be congruent with and/or precisely match the shape and contour of the depression 610 in land 600, so long as a sufficient electrical connection can be established between the bump 550 and land 600.

Disposed over the land 600 and depression 610—and between the land 600 and the conductive bump 550—is a layer of a conductive material 590. The conductive material layer 590 forms an electrical connection between the conductive bump 550 and the mating land 600. In one embodiment, the conductive material layer 590 comprises an anisotropic conductive material. In a further embodiment, the anisotropic material comprises a carrier material (e.g., a polymer) in which a plurality of conductive particles are suspended. In this embodiment, the anisotropic material is compressed between the land 600 and conductive bump 550 in a region overlying the depression 610. The anisotropic material is compressed to an extent that the suspended conductive particles in the region overlying depression 610 are in sufficient contact with one another to form an electrical connection between the conductive bump 550 and land 600 (e.g., the anisotropic material is conductive in at least the Z-direction in this region). As previously described with respect to FIG. 3B and the accompanying text above, the anisotropic material is non-conductive in the uncompressed state because the conductive particles do not make sufficient electrical contact with one another and, therefore, other portions of the anisotropic material (e.g., those regions not overlying depression 610) remain non-conductive.

In yet another embodiment, the conductive material layer 590 also comprises an adhesive material, and the conductive material layer 590 bonds the conductive bump 550 to the land 600, thereby providing a mechanical attachment (in addition to electrical connectivity) between the first and second components 510, 520. Once again, it should be understood that the disclosed embodiments are not limited to use of a conductive material layer 590 that is adhesive and/or that is an anisotropic.

Each of FIGS. 3A and 5 illustrate a portion of an assembly and each shows a single bond pad and mating land. However, as the reader will appreciate, the first component (310 or 510) in the embodiments of FIGS. 3 and 5, respectively, may include a number of lands (400 or 600) arranged in a pattern. Further, the second component (320 or 520) may include a number of bond pads (327 or 527), and these bond pads will be arranged in a pattern corresponding to the pattern of the lands. Each of the bond pads may be coupled with a conductive bump (350 or 550), and these conductive bumps may form electrical connections between the bond pads and lands. An example of a packaged IC device having an array of lands coupled with a corresponding array of bond pads according to the disclosed embodiments is described with respect to FIG. 9 and the accompanying text below.

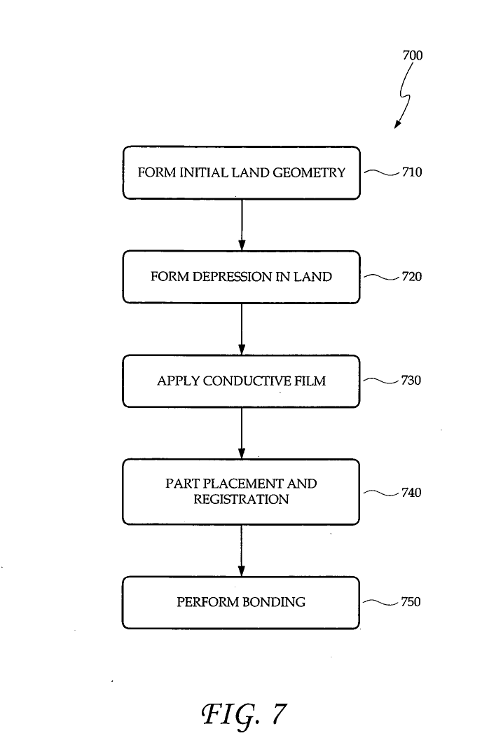

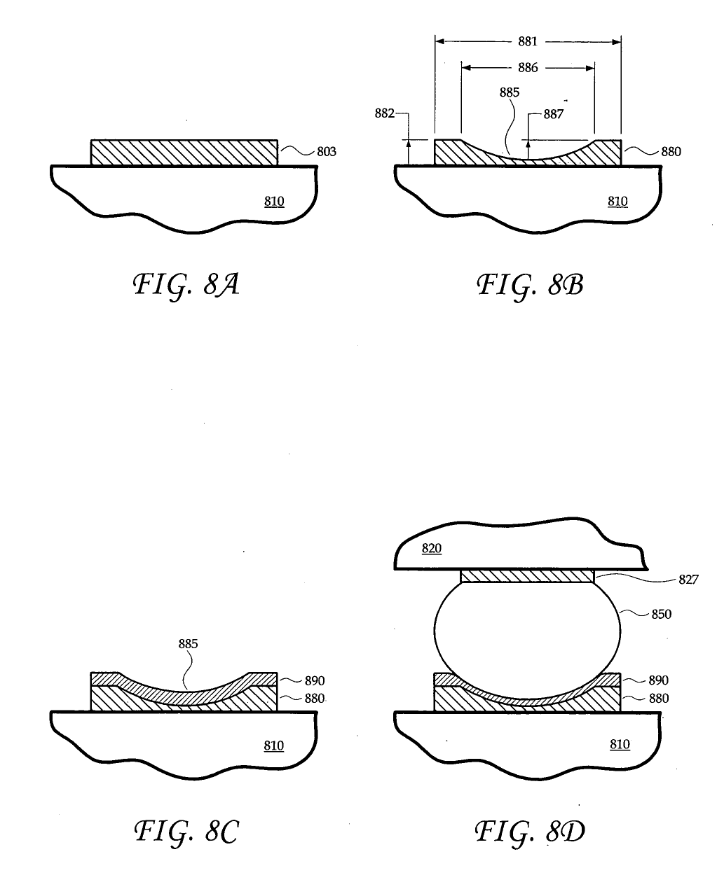

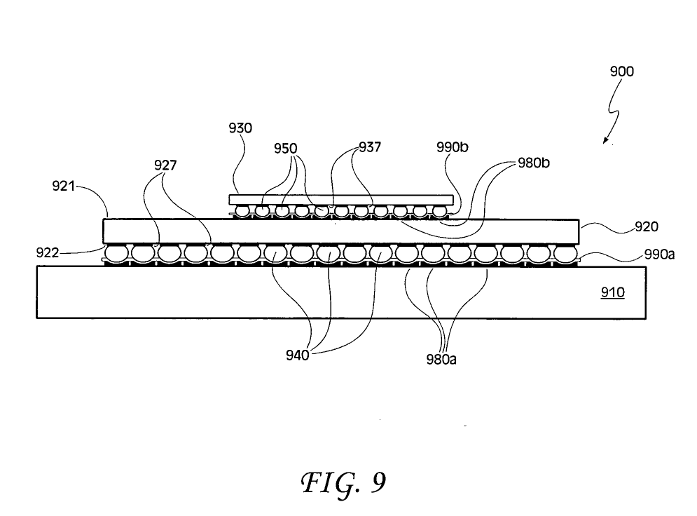

Illustrated in FIG. 7 are embodiments of a method of forming an electrical connection between two components. The embodiments shown in FIG. 7 are further illustrated in FIGS. 8A through 8D, and reference should be made to these figures as called out in the text.

Referring now to FIG. 7, and block 710 in particular, an initial land geometry is formed. This is illustrated in FIG. 8A, which shows an initial land geometry 803 formed on a first component 810. In one embodiment, the initial land geometry 803 comprises a generally cylindrical disk shaped body. The land may be formed from any suitable conductive material, such as copper, nickel, gold, silver, tin, or an alloy thereof. Also, although a single land is shown in FIG. 8A, it should be understood that an array of lands may be formed on the first component 810. The first component 810 may comprise a package substrate, a circuit board or other next-level component, or any other device.

Referring to block 720, a depression is formed in the initial land geometry. This is illustrated in FIG. 8B, where a depression 885 has been formed in the initial land geometry 803 to form a land 880. The depression 885 is shaped to receive a conductive bump (or other connection element) extending from another component (e.g., an IC die or package substrate). For example, the depression 885 may have a shape similar to that shown in any one of FIGS. 4A, 4B, or 6.

Any suitable process may be employed to form the depression 885. In one embodiment, the depression 885 is formed using a chemical etch process. For a chemical etch process, a mask layer (not shown in figures) may be disposed over portions of the initial land geometry 803, as well as portions of the first component 810. In some embodiments, the shape of the depression 885—e.g., any of the shapes shown in FIGS. 4A, 4B, and 6—may be a natural result of the chemical etch process. In another embodiment, the depression 885 is formed using a laser ablation process. For laser ablation processes, the desired shape of the depression may be achieved using any one (or combination) of a variety of techniques. By way of example, beam forming (e.g., variation in light intensity over the profile of the laser beam) may be used to create the desired shape. By way of further example, the desired shape my be created using a narrow beam and varying the power and/or speed of the beam as the beam traverses over the surface of the land. In a further embodiment, the land 880 and depression 885 are formed using a plate-up process and multiple imaging steps.

The land 880 and depression 885 may have, or be formed to, any suitable dimensions. In one embodiment, the land 880 has an outer dimension 881 of between 200 μm and 250 μm. For depression formation by chemical etching, the depression 885 may have a dimension 886 of between 50 μm and 100 μm. For depression formation by laser ablation, larger size depressions can be can be formed, even for smaller land dimensions. In one embodiment, the overall thickness 882 of the land 880 is between 25 μm and 75 μm, and the depression 885 is formed to a depth 887 of between 22 μm and 70 μm.

Referring to block 730, a conductive film is applied over the land and depression. This is illustrated in FIG. 8C, which shows a layer of conductive material 890 disposed over surfaces of the land 880 and depression 885. In one embodiment, the conductive material layer 890 comprises an anisotropic conductive material. In one embodiment, the anisotropic conductive material comprises a polymer material in which conductive particles are suspended. In another embodiment, the anisotropic material comprises an epoxy (e.g., a thermo-set epoxy) in which conductive particles have been suspended. In one embodiment, the anisotropic conductive material layer has a thickness of between 20 μm and 75 μm. Also, although a layer of conductive material 890 is shown overlying a single land in FIGS. 8A-8D, it will be appreciated that the first component 810 may include an array of lands 880, in which case the layer of conductive material 890 may comprise a sheet of anisotropic conductive material that overlies all (or a portion) of the array of lands.

Referring to block 740, a part is placed over the first component and registration is performed to align the land with its mating lead. This is illustrated in FIG. 8D, where a second component 820 has been placed over the first component 810. Second component 820 may comprise an IC die, a package substrate, or any other device. The second component 820 includes a lead or bond pad 827, and a conductive bump 850 is disposed on the bond pad 827. The conductive bump 850 may have any suitable shape (e.g., a generally spherical shape, a column shape, etc.) and may be formed from any suitable conductive material (e.g., solder). The depression 885 on land 850 will be shaped to received the conductive bump 850 extending from first component 810, and the mating interaction between the depression 885 of land 880 and the conductive bump 850 may assist in the registration and/or alignment between these two elements (and between the first and second components 810, 820 generally).

Referring to block 750, bonding is performed to electrically couple the land with its mating lead. This is also illustrated in FIG. 8D, where the conductive material layer 890 is electrically coupling the conductive bump 850 to the land 880. In one embodiment, as described above, the conductive material layer 890 comprises an anisotropic material that is compressed in a region overlying the depression 885 to form an electrical connection between the conductive bump 850 and land 880. As noted above, the anisotropic conductive film 890 may have a thickness (uncompressed) of between 20 μm and 75 μm, and in one embodiment, the anisotropic film is compressed up to 50% of its original, uncompressed thickness. However, it should be understood that the actual amount of compression of the anisotropic film will be a function of the specific application at hand and, further, that compression of the anisotropic film to an extent greater than 50% is within the scope of the disclosed embodiments.

In one embodiment, a compressive force is applied to the first and second components 810, 820 to compress the anisotropic material, and a low temperature cure (e.g., between 120° C. and 160° C.) is performed to bond (both electrically and mechanically) the conductive bump 850 and land 880. In another embodiment, one or more mechanical fasteners (e.g., spring clips) my be used to both compress the anisotropic conductive layer and attach the second component 820 to the first component 810. Note that because the conductive material layer 890 is utilized to electrically couple the land 880 with its mating lead 850, a solder reflow process is unnecessary and the first and second components 810, 820 are not subjected to the relatively higher temperatures needed for the reflow process (e.g., temperatures in a range of 220° C. to 260° C.).

As suggested above, the disclosed embodiments may be utilized to create electrical connections between any two devices. For example, the disclosed embodiments may be used to form electrical connections between an IC die and a package substrate and/or between a package substrate and a circuit board or other next-level component. This is illustrated in FIG. 9, which shows an embodiment of an assembly that incorporates some of the disclosed embodiments.

Referring to FIG. 9, an assembly 900 includes a die 930 that is disposed on a package substrate 920 which, in turn, is coupled with a circuit board 910 (or other next-level component). In the embodiment of FIG. 9, one or more of the disclosed embodiments have been employed to form electrical connections between the die 930 and package substrate 920, and one or more of the disclosed embodiments have been employed to form electrical connections between the package substrate 920 and circuit board 910. However, it should be understood that the disclosed embodiments may find application to other types of devices and, further, that an assembly may utilize one or more of the disclosed embodiments between only two components or between more than three components.

The circuit board 910 includes a number of lands 980a that have been formed according to any of the disclosed embodiments, each of the lands 980a including a depression shaped to receive one of a number of conductive bumps 940 extending from the package substrate 920. Each of the conductive bumps 940 extends from a lead or bond pad 927 formed on a surface 922 of the package substrate, and the package substrate includes an array of these bond pads that are arranged in a pattern corresponding to the arrangement of the lands 980a on circuit board 910. A sheet of conductive material 990a (e.g., an anisotropic conductive material) is disposed between the package substrate 920 and circuit board 910, and the conductive material layer 990a is used to form electrical connections between the conductive bumps 940 and lands 980a, as described above. Package substrate 920 also includes a number of lands 980b formed on an opposing surface 921, these lands 980b having been formed according to any of the disclosed embodiments. Each of the lands 980b includes a depression shaped to receive one of a number of conductive bumps 950 extending from the die 930. Each of the conductive bumps 950 is disposed on a bond pad 937 of the die 930, and the die includes an array of these bond pads 937 that are arranged in a pattern corresponding to the arrangement of the lands 980b on package substrate 920. Another sheet of conductive material 990b (e.g., an anisotropic material) is disposed between the die 930 and package substrate 920, and the conductive material layer 990b is used to form electrical connections between the conductive bumps 950 and lands 980b, as previously described.

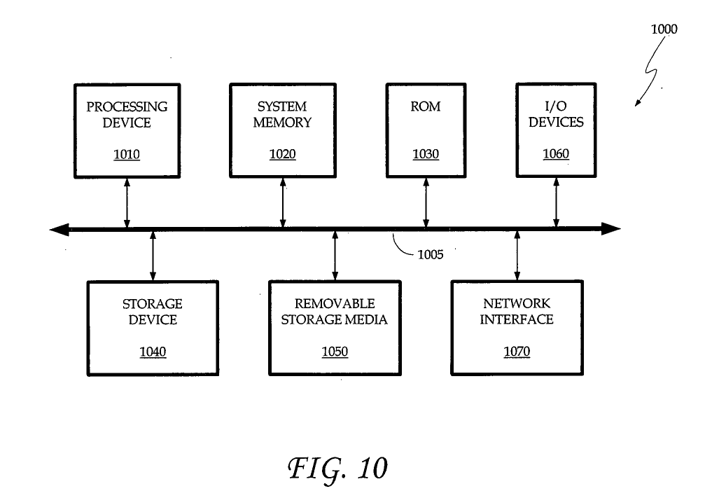

Referring to FIG. 10, illustrated is an embodiment of a computer system 1000. Computer system 1000 includes a bus 1005 to which various components are coupled. Bus 1005 is intended to represent a collection of one or more buses—e.g., a system bus, a Peripheral Component Interface (PCI) bus, a Small Computer System Interface (SCSI) bus, etc.—that interconnect the components of system 1000. Representation of these buses as a single bus 1005 is provided for ease of understanding, and it should be understood that the system 1000 is not so limited. Those of ordinary skill in the art will appreciate that the computer system 1000 may have any suitable bus architecture and may include any number and combination of buses.

Coupled with bus 1005 is a processing device (or devices) 1010. The processing device 1010 may comprise any suitable processing device or system, including a microprocessor, a network processor, an application specific integrated circuit (ASIC), or a field programmable gate array (FPGA), or similar device. It should be understood that, although FIG. 10 shows a single processing device 1010, the computer system 1000 may include two or more processing devices.

Computer system 1000 also includes system memory 1020 coupled with bus 1005, the system memory 1010 comprising, for example, any suitable type and number of memories, such as static random access memory (SRAM), dynamic random access memory (DRAM), synchronous DRAM (SDRAM), or double data rate DRAM (DDRDRAM). During operation of computer system 1000, an operating system and other applications may be resident in the system memory 1020.

The computer system 1000 may further include a read-only memory (ROM) 1030 coupled with the bus 1005. During operation, the ROM 1030 may store temporary instructions and variables for processing device 1010. The system 1000 may also include a storage device (or devices) 1040 coupled with the bus 1005. The storage device 1040 comprises any suitable non-volatile memory, such as, for example, a hard disk drive. The operating system and other programs may be stored in the storage device 1040. Further, a device 1050 for accessing removable storage media (e.g., a floppy disk drive or a CD ROM drive) may be coupled with bus 1005.

The computer system 1000 may also include one or more I/O (Input/Output) devices 1060 coupled with the bus 1005. Common input devices include keyboards, pointing devices such as a mouse, as well as other data entry devices, whereas common output devices include video displays, printing devices, and audio output devices. It will be appreciated that these are but a few examples of the types of I/O devices that may be coupled with the computer system 1000.

The computer system 1000 further comprises a network interface 1070 coupled with bus 1005. The network interface 1070 comprises any suitable hardware, software, or combination of hardware and software that is capable of coupling the system 1000 with a network (e.g., a network interface card). The network interface 1070 may establish a link with the network (or networks) over any suitable medium—e.g., wireless, copper wire, fiber optic, or a combination thereof- supporting the exchange of information via any suitable protocol—e.g., TCP/IP (Transmission Control Protocol/Internet Protocol), HTTP (Hyper-Text Transmission Protocol), as well as others.

It should be understood that the computer system 1000 illustrated in FIG. 10 is intended to represent an exemplary embodiment of such a system and, further, that this system may include many additional components, which have been omitted for clarity and ease of understanding. By way of example, the system 1000 may include a DMA (direct memory access) controller, a chip set associated with the processing device 1010, additional memory (e.g., a cache memory), as well as additional signal lines and buses. Also, it should be understood that the computer system 1000 may not include all of the components shown in FIG. 10.

In one embodiment, the die 930 and package substrate 920 (and, perhaps, the circuit board 910) of FIG. 9—which have been electrically connected to one another according to any of the disclosed embodiments—comprises a component of the computer system 1000. For example, the processing device 1010 of system 1000 may be embodied as the die 930 which has been electrically coupled with the package substrate 920 according to any of the disclosed embodiments. However, it should be understood that any other component of system 1000 (e.g., system memory 1020, network interface 1070, etc.) may include two or more components that have been electrically connected according to the disclosed embodiments.

The foregoing detailed description and accompanying drawings are only illustrative and not restrictive. They have been provided primarily for a clear and comprehensive understanding of the disclosed embodiments and no unnecessary limitations are to be understood therefrom. Numerous additions, deletions, and modifications to the embodiments described herein, as well as alternative arrangements, may be devised by those skilled in the art without departing from the spirit of the disclosed embodiments and the scope of the appended claims.

1. An apparatus comprising:
a conductive land disposed on a first component, the land having a depression shaped to receive a conductive bump extending from a second component; and
a layer of a conductive material disposed over the land and the depression, the conductive material layer to form electrical contact with the conductive bump extending from the second component and into the depression.

2. The apparatus of claim 1, wherein the conductive material layer comprises an anisotropic conductive material.

3. The apparatus of claim 2, wherein the electrical contact with the conductive bump of the second component is created by compression of the anisotropic conductive material in a region overlying the depression.

4. The apparatus of claim 3, wherein the anisotropic material comprises an adhesive material to physically attach the conductive bump of the second component to the land.

5. The apparatus of claim 1, wherein the first component comprises a package substrate and the second component comprises an integrated circuit die.

6. The apparatus of claim 1, wherein the first component comprises a circuit board and the second component comprises a package substrate.

7. An apparatus comprising:
a substrate;
a number of conductive lands disposed on the substrate, each of the lands having a depression shaped to receive one of a number of conductive bumps extending from a component; and
a layer of an anisotropic conductive material disposed over each of the lands and depressions, the anisotropic conductive material layer on each land to form electrical contact with the mating one conductive bump extending from the component and into the depression of that land.

8. The apparatus of claim 7, wherein the electrical contact with the mating one conductive bump of the component is created by compression of the anisotropic conductive material in a region overlying the depression of that land.

9. The apparatus of claim 8, wherein the anisotropic material on each land comprises an adhesive material to physically attach the mating one conductive bump of the component to the land.

10. The apparatus of claim 9, wherein the anisotropic conductive material of each of the lands comprises a single sheet of material.

11. The apparatus of claim 7, wherein the substrate comprises a package substrate and the component comprises an integrated circuit die.

12. The apparatus of claim 7, wherein the substrate comprises a circuit board and the component comprises a package substrate.

13. An assembly comprising:
a first component, the first component having a number of conductive bumps arranged in a pattern;
a second component, the second component having a number of lands arranged in a pattern corresponding to the pattern of the leads, each of the lands having a depression shaped to receive a mating one of the number of leads; and
a sheet of anisotropic conductive material disposed between the first and second components, the anisotropic conductive material to form electrical contact between each land and its mating one conductive bump.

14. The assembly of claim 13, wherein the electrical contact between each land and its mating conductive bump is created by compression of the anisotropic conductive sheet in a region overlying the depression of that land.

15. The assembly of claim 14, wherein the anisotropic conductive sheet comprises an adhesive material to physically attach each land to its mating one conductive bump.

16. The assembly of claim 13, wherein the first component comprises an integrated circuit die and the second component comprises a package substrate.

17. The assembly of claim 13, wherein first component comprises a package substrate and the second component comprises a circuit board.

18. A method comprising:
providing a land disposed on a substrate;
forming a depression in the land, the depression shaped to receive a conductive bump extending from a component; and
applying a layer of a conductive material over the land and the depression, the conductive material to form electrical contact between the land and the conductive bump.

19. The method of claim 18, wherein the conductive material layer comprises an anisotropic conductive material.

20. The method of claim 19, wherein the electrical contact with the conductive bump of the component is created by compression of the anisotropic conductive material in a region overlying the depression.

21. The method of claim 20, wherein the anisotropic material comprises an adhesive material to physically attach the conductive bump of the second component to the land.

22. The method of claim 18, wherein the substrate comprises a package substrate and the component comprises an integrated circuit die.

23. The method of claim 18, wherein the substrate comprises a circuit board and the component comprises a package substrate.

24. A method comprising:
providing a number of lands disposed on a first component, the lands arranged in a pattern;
providing a second component, the second component having a number of conductive bumps arranged in a pattern corresponding to the pattern of the lands;
forming a depression in each of the lands, each depression shaped to receive a mating one of the conductive bumps of the second component;
placing a sheet of an anisotropic conductive material between the lands of the first component and the conductive bumps of the second component; and
forming electrical connections between the lands and the conductive bumps using the sheet of anisotropic conductive material.

25. The method of claim 24, wherein forming the electrical connections comprises compressing the anisotropic conductive material in regions overlying the depressions formed in the lands.

26. The method of claim 24, further comprising attaching the second component to the first component.

27. The method of claim 26, wherein the anisotropic conductive material comprises an adhesive material and the anisotropic material is used to attach the first and second components.

28. The method of claim 26, comprising aligning the first and second components using the depressions formed in the lands.

29. The method of claim 24, wherein the first component comprises a package substrate and the second component comprises an integrated circuit die.

30. The method of claim 24, wherein the first component comprises a circuit board and the second component comprises a package substrate.

31. A system comprising:
a memory; and
a processing device coupled with the memory, the processing device including
a die, the die having a number of conductive bumps arranged in a pattern,
a package substrate, the package substrate having a number of lands arranged in a pattern corresponding to the pattern of the conductive bumps, each of the lands having a depression shaped to receive a mating one of the conductive bumps, and
a sheet of anisotropic conductive material disposed between the die and package substrate, the anisotropic conductive material to form electrical contact between each land and its mating one conductive bump.

32. The system of claim 31, wherein the electrical contact between each land and its mating conductive bump is created by compression of the anisotropic conductive sheet in a region overlying the depression of that land.

33. The system of claim 32, wherein the anisotropic conductive sheet comprises an adhesive material to physically attach each land to its mating one conductive bump.
